(19) United States
(12) Patent Application Publication
(10) Pub. No.: US 2021/0291698 A1
(43) Pub. Date: Sep. 23, 2021

(54) DIAGNOSTIC DEVICE, DIAGNOSTIC METHOD, AND PROGRAM

(71) Applicant: HONDA MOTOR CO., LTD., Minato-ku, Tokyo (JP)

(72) Inventor: Yoshikazu Nishida, Wako-shi (JP)

(21) Appl. No.: 17/267,048

(22) PCT Filed: Jun. 7, 2019
(86) PCT No.: PCT/JP2019/022674

§ 371 Date: Feb. 9, 2021

(30) Foreign Application Priority Data
Aug. 28, 2018 (JP) 2018-159086
Jan. 28, 2019 (JP) 2019-011828

(51) Int. Cl. B60L 58/16; B60L 58/13; B60W 20/13; B60W 50/00; B60W 50/14; G06N 3/02

(52) U.S. Cl. CPC B60L 58/16; B60L 58/13; B60W 20/13; B60W 50/0097; B60W 2050/146; G06N 3/02; B60W 2510/246; B60W 2510/248; B60W 2510/244; B60W 50/14

(57) ABSTRACT

A diagnostic device includes: an acquirer configured to acquire information indicating a use status and the degree of deterioration of each secondary battery from a plurality of secondary batteries which are mounted in a plurality of vehicles including an target vehicle; a model generator configured to generate a model that is configured to output a battery capacity when a use state is input thereto on the basis of the information acquired by the acquirer; and a deriver configured to derive a future state of the secondary battery mounted in the target vehicle using the model.

### TECHNICAL FIELD

The present invention relates to a diagnostic device, a diagnostic method, and a program.

Priority is claimed on Japanese Patent Application No. 2018-159086, filed Aug. 28, 2018, and Japanese Patent Application No. 2019-011828, filed Jan. 28, 2019, the contents of which are incorporated herein by reference.

### BACKGROUND ART

There are electric vehicles having a traveling motor mounted therein or hybrid vehicles including a traveling motor and an engine. A motor which is mounted in a vehicle is driven with electric power supplied from a secondary battery such as a battery. In such a secondary battery, a problem that a state of charge is decreased due to deterioration or the like occurs. Therefore, a technique of determining the degree of deterioration of a secondary battery and curbing deterioration of the secondary battery is known (for example, see Patent Document 1). The degree of deterioration of the secondary battery is calculated, for example, based on an integrated value of electric power discharged from the secondary battery and a voltage drop which are calculated based on the current value, the voltage value, the temperature, and the like of the secondary battery.

### CITATION LIST

### Patent Literature

[Patent Document 1]

Japanese Unexamined Patent Application, First Publication No. 2015-162991

### SUMMARY OF INVENTION

### Technical Problem

In curbing deterioration of a secondary battery, when the accuracy for determination of the degree of deterioration of the secondary battery is low, it is difficult to take appropriate countermeasures. However, when the degree of deterioration of the secondary battery is determined on the basis of an integrated value of electric power discharged from the secondary battery and a voltage drop which are calculated based on only a current value detected from the secondary battery, it is difficult to guarantee satisfactory accuracy.

The invention was made in consideration of the above-mentioned circumstances and an objective thereof is to provide a diagnostic device, a diagnostic method, and a program that can derive the degree of deterioration of a secondary battery with high accuracy.

### Solution to Problem

A diagnostic device, a diagnostic method, and a program according to the invention employ the following configurations.

(1) An aspect of the invention provides a diagnostic device including: an acquirer configured to acquire information indicating the use status and the degree of deterioration of each secondary battery from a plurality of secondary batteries which are mounted in a plurality of vehicles including an target vehicle; a model generator configured to generate a model that is configured to output a battery capacity in a case where a use state is input thereto on the basis of the information acquired by the acquirer; and a deriver configured to derive a future state of the secondary battery mounted in the target vehicle using the model.

(2) In the aspect (1), the deriver is further configured to derive deterioration curves of the plurality of secondary batteries on the basis of the model, and to deriver the future state of the secondary battery mounted in the target vehicle on the basis of the deterioration curves and a designated deterioration ratio.

(3) In the aspect (1) or (2), the model generator is configured to generate the model by machine learning.

(4) In any one of the aspects (1) to (3), the use status of each secondary battery includes at least one of the current value, the voltage value, the temperature, and a total elapsed usage time of the secondary battery.

(5) In any one of the aspects (1) to (4), the model generator is configured to generate the model on the basis of information on the same type of secondary batteries.

(6) In any one of the aspects (1) to (4), the model generator is configured to generate the model on the basis of information on the same type of secondary batteries which are mounted in the same type of vehicles.

(7) In any one of the aspects (1) to (6), the future state may be a lifespan, and the diagnostic device may further include a display controller configured to display the lifespan of the secondary battery derived by the deriver on a display.

(8) In the aspect (7), the display may be provided in the target vehicle.

(9) In the aspect (7), the display may be provided in a prescribed information terminal.

(10) In any one of the aspects (7) to (9), the display controller is configured to display the lifespan on the display using at least one of durability years or durability days.

(11) In the aspect (1), the future state may be a residual value, and the diagnostic device may further include: a display controller configured to display an interface screen including an object indicating transition of the residual value derived by the deriver on a display; and a receiver configured to receive transition of the residual value in a state in which the interface screen is displayed on the display.

(12) In the aspect (11), the display controller is configured to display an interface screen including a plurality of objects on the display, and the wherein the receiver is configured to receive transition of the residual value associated with the object selected by a user out of the plurality of objects included in the interface screen.

(13) In the aspect (11) or (12), the display controller is further configured to display the interface screen including a deterioration allowable limit of the secondary battery on the display.

(14) The diagnostic device according to any one of the aspects (11) to (13) may further include an adjuster configured to adjust a use mode associated with deterioration of the secondary battery on the basis of transition of the residual value received by the receiver.

(15) In the aspect (14), the adjuster is configured to adjust an SOC use range of the secondary battery as the use mode associated with deterioration of the secondary battery.

(16) In the aspect (14) or (15), the adjuster is configured to adjust a priority of performance exhibition of a vehicle with respect to curbing of deterioration of the secondary battery as the use mode associated with deterioration of the secondary battery.

(17) In any one of the aspects (14) to (16), the vehicle may be a hybrid vehicle including the secondary battery and an internal combustion engine, and the adjuster is configured to adjust a priority of use of the internal combustion engine with respect to curbing of deterioration of the secondary battery as the use mode associated with deterioration of the secondary battery.

(18) An aspect of the invention provides a diagnostic method using a computer, acquiring information indicating the use status and the degree of deterioration of each secondary battery from a plurality of secondary batteries which are mounted in a plurality of vehicles including an target vehicle; generating a model that is configured to output a battery capacity in a case where a use state is input thereto on the basis of the acquired information; and deriving a future state of the secondary battery mounted in the target vehicle using the model.

(19) An aspect of the invention provides a program for causing a computer to: acquire information indicating the use status and the degree of deterioration of each secondary battery from a plurality of secondary batteries which are mounted in a plurality of vehicles including an target vehicle; generating a model that is configured to output a battery capacity in a case where a use state is input thereto on the basis of the acquired information; and deriving a future state of the secondary battery mounted in the target vehicle using the model.

### Advantageous Effects of Invention

According to the aspects (1) to (19), it is possible to derive the degree of deterioration of a secondary battery with high accuracy.

According to the aspects (7) to (10), it is possible to notify a user of the degree of deterioration of a secondary battery with high accuracy.

According to the aspects (11) to (17), it is possible to set the use state and a future state of a secondary battery depending on a user's taste.

### BRIEF DESCRIPTION OF DRAWINGS

FIG. 1 is a diagram showing an example of a configuration of a diagnostic system 1 according to a first embodiment.

FIG. 2 is a diagram showing an example of a configuration of a vehicle 10.

FIG. 3 is a diagram showing an example of a configuration of a passenger compartment of the vehicle 10.

FIG. 4 is a diagram showing an example of a screen which is displayed on a display 62.

FIG. 5 is a flowchart showing an example of a flow of processes which are performed by constituent units of a center server 100.

FIG. 6 is a conceptual diagram showing a process of generating a capacity estimation model 154.

FIG. 7 is a conceptual diagram showing the process of generating the capacity estimation model 154 which is subsequent to FIG. 6.

FIG. 8 is a diagram showing a deterioration ratio transition model generating process.

FIG. 9 is a diagram showing a representative transition line REL.

FIG. 10 is a diagram showing an example of a configuration of a vehicle 10A according to a second embodiment.

FIG. 11 is a diagram showing an example of a configuration of a vehicle 10B according to a third embodiment.

FIG. 12 is a diagram showing an example of a plurality of transition lines.

FIG. 13 is a diagram showing an example of a plurality of residual value transition lines which are displayed on a touch panel 66.

FIG. 14 is a diagram showing an example of a screen which is displayed on a display 410 of a mobile terminal 400.

### DESCRIPTION OF EMBODIMENTS

Hereinafter, embodiments of a diagnostic device, a diagnostic method, and a program according to the invention will be described with reference to the accompanying drawings. In the following description, a vehicle 10 is assumed to be an electric vehicle, but the vehicle 10 may be a hybrid vehicle or a fuel-cell vehicle as long as it is a vehicle in which a secondary battery that supplies traveling electric power is mounted.

### First Embodiment

[Entire Configuration]

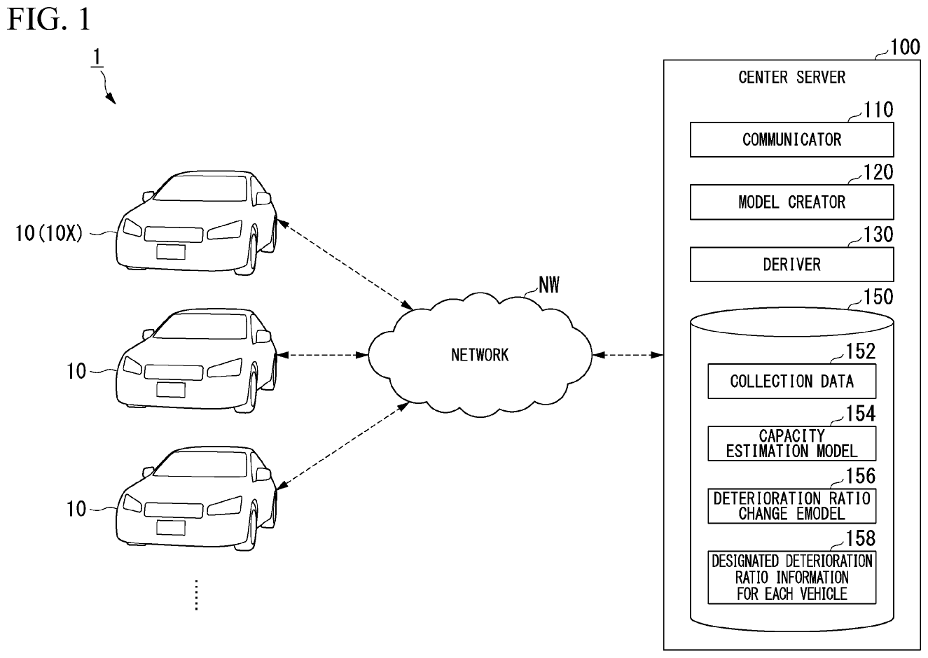

FIG. 1 is a diagram showing an example of a configuration of a diagnostic system 1 according to a first embodiment. The diagnostic system 1 is a battery deterioration diagnosis system that diagnoses deterioration of a battery (hereinafter, which is synonymous with a secondary battery) which is mounted in a vehicle 10. As shown in FIG. 1, the diagnostic system 1 includes a plurality of vehicles 10 and a center server (a diagnostic device) 100. In the following description, a vehicle 10 which transmits battery use status information and in which a designated deterioration ratio arrival time is displayed out of the plurality of vehicles 10 is defined as an target vehicle 10X.

The center server 100 diagnoses the batteries mounted in a plurality of vehicles 10 on the basis of information transmitted from the plurality of vehicles 10. The vehicles 10 and the center server 100 communicate with each other via a network NW. The network NW includes, for example, the Internet, a wide area network (WAN), a local area network (LAN), a provider device, and a radio base station.

[Vehicle 10]

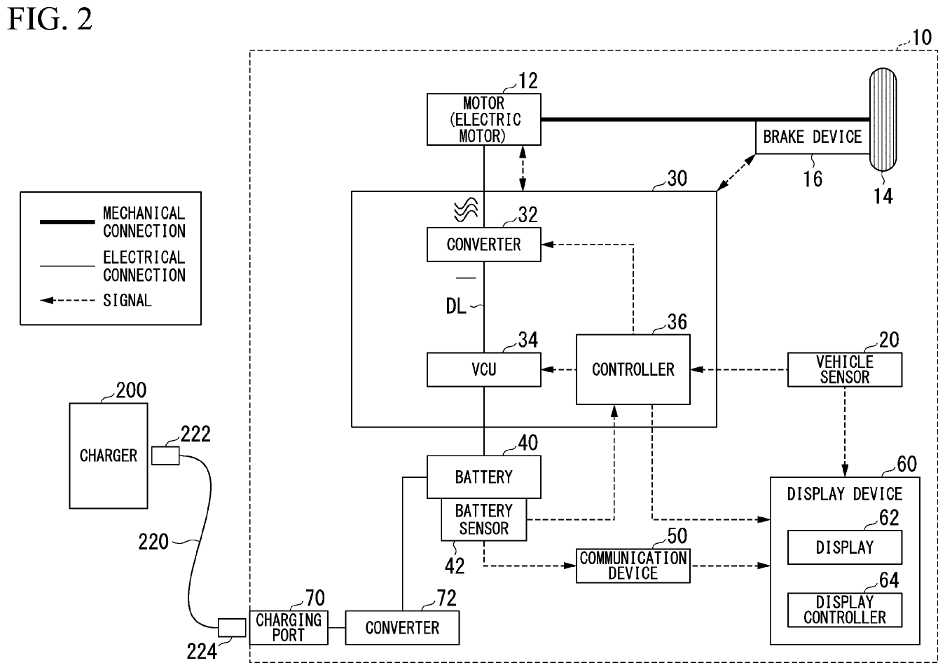

FIG. 2 is a diagram showing an example of a configuration of each vehicle 10. As shown in FIG. 2, the vehicle 10 includes, for example, a motor 12, driving wheels 14, a brake device 16, a vehicle sensor 20, a power control unit (PCU) 30, a battery 40, a battery sensor 42 such as a voltage sensor, a current sensor, and a temperature sensor, a communication device 50, a display device 60, a charging port 70, and a converter 72.

The motor 12 is, for example, a three-phase alternating current electric motor. A rotor of the motor 12 is connected to the driving wheels 14. The motor 12 outputs power to the driving wheels 14 using electric power supplied thereto. The motor 12 generates electric power using kinetic energy of the vehicle at the time of deceleration of the vehicle.

The brake device 16 includes, for example, a brake caliper, a cylinder that transmits a hydraulic pressure to the brake caliper, and an electric motor that generates a hydraulic pressure in the cylinder. The brake device 16 may include a mechanism for transmitting a hydraulic pressure generated by an operation of a brake pedal to the cylinder via a master cylinder as a backup. The brake device 16 is not limited to the aforementioned configuration, and may be an electronically controlled hydraulic brake device that transmits the hydraulic pressure of the master cylinder to the cylinder.

The vehicle sensor 20 includes an accelerator depression sensor, a vehicle speed sensor, and a brake depression sensor. The accelerator depression sensor is attached to an accelerator pedal which is an example of an operator receiving an acceleration instruction from a driver, detects the amount of depression of the accelerator pedal, and outputs the detected amount of depression as an accelerator operation amount to a controller 36. The vehicle speed sensor includes, for example, a wheel speed sensor attached to each wheel and a speed calculator, derives a speed of the vehicle (a vehicle speed) by combining wheel speeds detected by the wheel speed sensors, and outputs the derived vehicle speed to the controller 36 and the display device 60. The brake depression sensor is attached to a brake pedal, detects the amount of depression of the brake pedal, and outputs the detected amount of depression as a brake depression amount to the controller 36.

The PCU 30 includes, for example, a converter 32, a voltage control unit (VCU) 34, and a controller 36. A configuration in which these elements are unified as a single PCU 34 is only an example, and these elements may be distributed and arranged.

The converter 32 is, for example, an AC-DC converter. A DC-side terminal of the converter 32 is connected to a DC link DL. The DC link DL is connected to the battery 40 via the VCU 34. The converter 32 converts AC electric power generated by the motor 12 into DC electric power and outputs the DC electric power to the DC link DL.

The VCU 34 is, for example, a DC-DC converter. The VCU 34 steps up a voltage of electric power which is supplied from the battery 40 and outputs the stepped-up electric power to the DC link DL.

The controller 36 includes, for example, a motor controller, a brake controller, and a battery/VCU controller. The motor controller, the brake controller, and the battery/VCU controller may be replaced with individual controllers, for example, controllers such as a motor ECU, a brake ECU, and a battery ECU, respectively.

The motor controller controls the motor 12 on the basis of the output of the vehicle sensor 20. The brake controller controls the brake device 16 on the basis of the output of the vehicle sensor 20. The battery/VCU controller calculates a state of charge (SOC) of the battery 40 (hereinafter also referred to as a “battery SOC”) on the basis of the output of the battery sensor 42 attached to the battery 40 and outputs the calculated battery SOC to the VCU 34 and the display device 60. The VCU 34 increases the voltage of the DC link DL in accordance with an instruction from the battery/VCU controller.

The battery 40 is a secondary battery such as a lithium-ion battery. The battery 40 stores electric power which is supplied from an external charger 200 outside of the vehicle 10 and performs discharging for traveling of the vehicle 10. The battery sensor 42 includes, for example, a current sensor, a voltage sensor, and a temperature sensor. The battery sensor 42 detects, for example, the current value, the voltage value, and the temperature of the battery 40. The battery sensor 42 outputs the detected current value, the detected voltage value, the detected temperature, and the like to the controller 36 and the communication device 50.

The communication device 50 includes a radio module for connection to a cellular network or a Wi-Fi network. The communication device 50 acquires battery use status information such as the current value, the voltage value, and the temperature, and the like which are output from the battery sensor 42 and transmits the acquired battery use status information to the center server 100 via the network NW shown in FIG. 1. The communication device 50 adds battery type information and vehicle type information of the host vehicle to the battery use status information to be transmitted. The communication device 50 receives information transmitted from the center server 100 via the network NW. The communication device 50 outputs the received information to the display device 60.

The display device 60 includes, for example, a display 62 and a display controller 64. The display 62 displays information based on the control of the display controller 64. The display controller 64 displays a battery SOC and designated deterioration ratio arrival days on the display 62 on the basis of information which is output from the controller 36 and the communication device 50. The display controller 64 displays a vehicle speed which is output from the vehicle sensor 20 or the like on the display 62.

The charging port 70 is provided to face the outside of the vehicle body of the vehicle 10. The charging port 70 is connected to a charger 200 via a charging cable 220. The charging cable 220 includes a first plug 222 and a second plug 224. The first plug 222 is connected to the charger 200 and the second plug 224 is connected to the charging port 70. Electric power which is supplied from the charger 200 is supplied to the charging port 70 via the charging cable 220.

The charging cable 220 includes a signal cable which is additionally provided in an electric power cable. The signal cable relays communication between the vehicle 10 and the charger 200. Accordingly, each of the first plug 222 and the second plug 224 includes an electric power connector and a signal connector.

The converter 72 is provided between the charging port 70 and the battery 40. The converter 72 converts a current which is introduced from the charger 200 via the charging port 70, for example, an AC current, into a DC current. The converter 72 outputs the converted DC current to the battery 40.

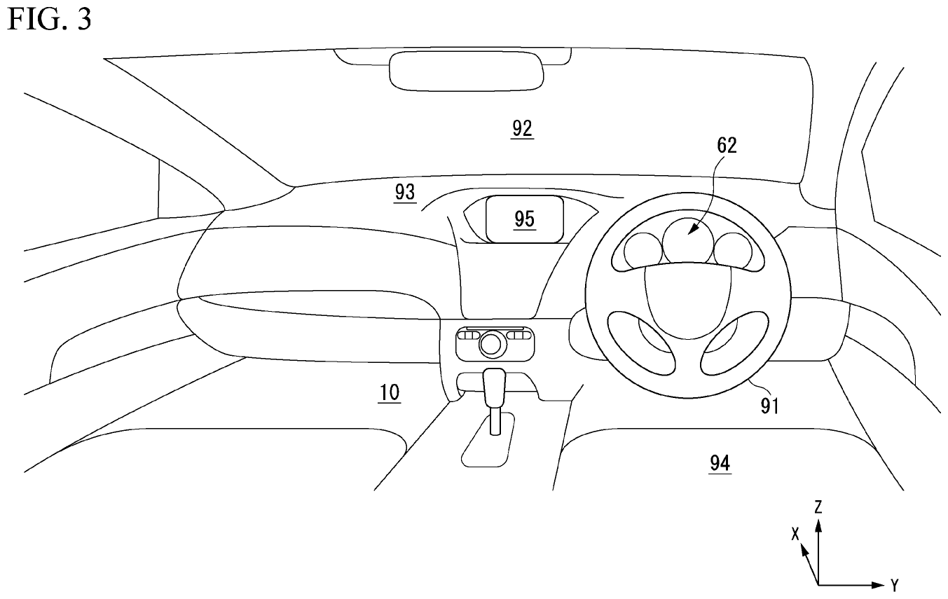

FIG. 3 is a diagram showing an example of a configuration of a passenger compartment of the vehicle 10. As shown in FIG. 2, for example, a steering wheel 91 that controls steering of the vehicle 10, a front windshield 92 that partitions the inside and the outside, and an instrument panel 93 are provided in the vehicle 10. The front windshield 92 is a member that transmits light.

The display 62 of the display device 60 is provided in the vicinity of the front of a driver seat 94 in the instrument panel 93 of the passenger compartment. The display 62 is visible through a gap of a steering wheel 91 or over the steering wheel 91 by a driver. A second display device 95 is provided at the center of the instrument panel 93. For example, the second display device 95 displays an image corresponding to a navigation process which is performed by a navigation device (not shown) mounted in the vehicle 10 or displays a video of a communication partner in a television call. The second display device 95 may display a television program, reproduce a DVD, or display contents such as downloaded movies.

[Center Server 100]

The center server 100 shown in FIG. 1 includes, for example, a communicator (acquirer) 110, a model generator 120, a deriver 130, and a storage 150. The model generator 120 and the deriver 130 are realized, for example, by causing a hardware processor such as a central processing unit (CPU) to execute a program (software). Some or all of such elements may be realized in hardware (which includes circuitry) such as a large scale integration (LSI), an application specific integrated circuit (ASIC), a field-programmable gate array (FPGA), or a graphics processing unit (GPU) or may be realized in cooperation of software and hardware. The program may be stored in a storage device such as a hard disk drive (HDD) or a flash memory (a non-transitory storage medium) in advance, or may be stored in a removable storage medium (a non-transitory storage medium) such as a DVD or a CD-ROM and installed by installing the storage medium in a drive device. The storage 150 is realized by the above-mentioned storage device.

The communicator 110 receives and acquires information such as the current value, the voltage value, the temperature, and the total elapsed usage time of the battery which are transmitted from a plurality of vehicles 10. The communicator 110 stores the received information as collected data 152 in the storage 150 for each piece of identification information (for example, number plate information, communication identification information of the communication device 50, or identification information of a registered user) of each vehicle 10. Battery type information or vehicle type information may be added to the collected data 152.

As the premise that processes are performed by the center server 100, a plurality of vehicles 10 detect a current value, a voltage value, and a temperature of the battery 40 using the battery sensor 42, and transmit the detected information as battery use status information from the communication device 50 to the center server 100. Each vehicle 10 may perform transmission of battery use status information at predetermined time intervals, for example, every hour or every day or may perform the transmission of battery use status information in response to an instruction from a user of the vehicle 10. Each vehicle 10 may perform transmission of battery use status information in response to a request from the center server 100. Each vehicle 10 may transmit battery use status information when predetermined conditions are satisfied, for example, when a battery load is greater than a predetermined value or when an increase of the battery load based on previous transmission reaches a predetermined value. Each vehicle 10 may transmit battery use status information at two or more of these times.

The model generator 120 calculates a battery capacity (the degree of deterioration of the battery) on the basis of the collected data 152 (the current value, the voltage value, the temperature, and the total elapsed usage time of the battery) which is acquired by the communicator 110 and which is stored in the storage 150. The model generator 120 generates a capacity estimation model 154 by performing machine learning using the calculated battery capacity as supervised data and using the collected data 152 stored in the storage 150 as training data. Since the battery capacity decreases with deterioration of the battery, the battery capacity serves as an index indicating the degree of deterioration of the battery.

For example, the model generator 120 generates the capacity estimation model 154 including neural network models in the whole market of batteries with data on the same type of batteries (a current value I, a voltage value V, a temperature T, and a total elapsed usage time) as an input and with the battery capacity (the battery SOC) as an output as a battery deterioration model. The market refers to an area in which vehicles providing data for generating the capacity estimation model 154 are located, for example, an area which is determined on the basis of appropriate conditions such as geographical conditions or quantitative conditions. The model generator 120 stores the generated capacity estimation model 154 in the storage 150.

The model generator 120 integrates the output of the capacity estimation model 154 at the time of generation of the capacity estimation model 154. The model generator 120 generates a deterioration ratio transition model 156 by performing statistical processing such as regression analysis or cluster processing on the integrated value of the output of the capacity estimation model. The model generator 120 stores the generated deterioration ratio transition model 156 in the storage 150.

The storage 150 stores designated deterioration ratio information 158 which is designated by a user of a vehicle 10 for each vehicle 10. The designated deterioration ratio information 158 is information indicating a battery deterioration ratio (a designated deterioration ratio) of a battery which is used to determine that the battery has deteriorated. The battery deterioration ratio is defined, for example, as a ratio by which the battery capacity has decreased from an initial state thereof. For example, the battery deterioration ratio is defined to be 10% when the battery capacity has decreased by 10%. The designated deterioration ratio may be received, for example, from the vehicle 10 or may be input to an input means which is not shown (a dealer terminal, a repair shop terminal, or a mobile terminal such as a smartphone) and transmitted to the center server 100 when the battery is mounted in the vehicle 10.

The deriver 130 derives a time until the designated deterioration ratio will be reached (hereinafter referred to as a “designated deterioration ratio arrival time”) on the basis of the collected data 152, the capacity estimation model 154, the deterioration ratio transition model 156, and the designated deterioration ratio information 158 for each vehicle 10 stored in the storage 150. The deriver 130 outputs the derived designated deterioration ratio arrival time to the communicator 110. The communicator 110 transmits the designated deterioration ratio arrival time output from the deriver 130 to an target vehicle 10X.

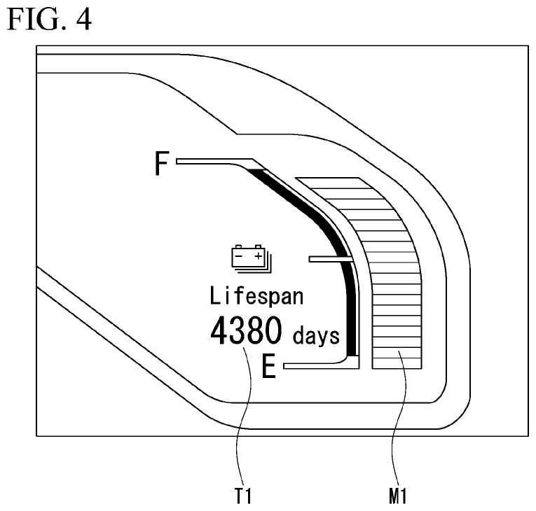

The target vehicle 10X displays information based on the transmitted designated deterioration ratio arrival time on the display 62 of the display device 60. FIG. 4 is a diagram showing an example of a screen which is displayed on the display 62. As shown in FIG. 4, for example, designated deterioration ratio arrival days T1 and a battery SOC meter M1 are displayed on the display 62. The designated deterioration ratio arrival days T1 are displayed by numerals and the battery SOC meter M1 is displayed by a meter.

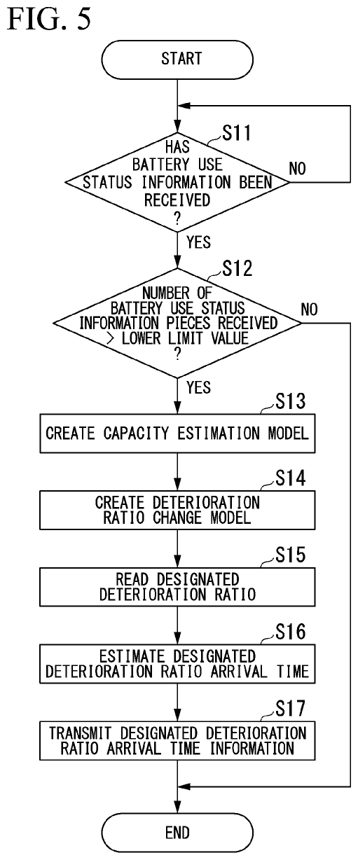

A process routine which is performed by the center server 100 will be described below in more detail. FIG. 5 is a flowchart showing an example of a process routine which is performed by the constituent units of the center server 100. Processes for generating a model (Steps S12 to S14) and processes for estimating a designated deterioration ratio arrival time (Steps S15 to S17) in FIG. 5 are shown in the same flowchart, but they may be independently performed asynchronously.

As shown in FIG. 5, the center server 100 determines whether battery use status information transmitted from a plurality of vehicles 10 has been received (Step S11). When it is determined that battery use status information has not been received (Step S11: NO), the center server 100 repeatedly performs the process of Step S11.

When it is determined that battery use status information has been received (Step S11: YES), the center server 100 determines whether the number of received pieces of battery use status information is greater than a lower limit value (Step S12). The lower limit value of the number of pieces of battery use status information is the number of pieces of data which is required for generating a battery deterioration model and can be set to an appropriate number. The center server 100 can generate a battery deterioration model with increasing accuracy as the number of pieces of battery use status information becomes greater. Accordingly, the center server 100 may set the number of pieces of data with which a battery deterioration model with predetermined accuracy can be generated as the lower limit value of the number of pieces of battery use status information. After the number of pieces of battery use status information has been greater than the lower limit value once, the determination of Step S12 may be skipped.

When it is determined that the number of pieces of battery use status information is not greater than the lower limit value (Step S12: NO), the center server 100 ends the process routine shown in FIG. 5 without any operation. When it is determined that the number of pieces of battery use status information is greater than the lower limit value (Step S12: YES), the center server 100 causes the model generator 120 to generate the capacity estimation model 154 (Step S13). The model generator 120 generates the capacity estimation model 154, for example, as follows.

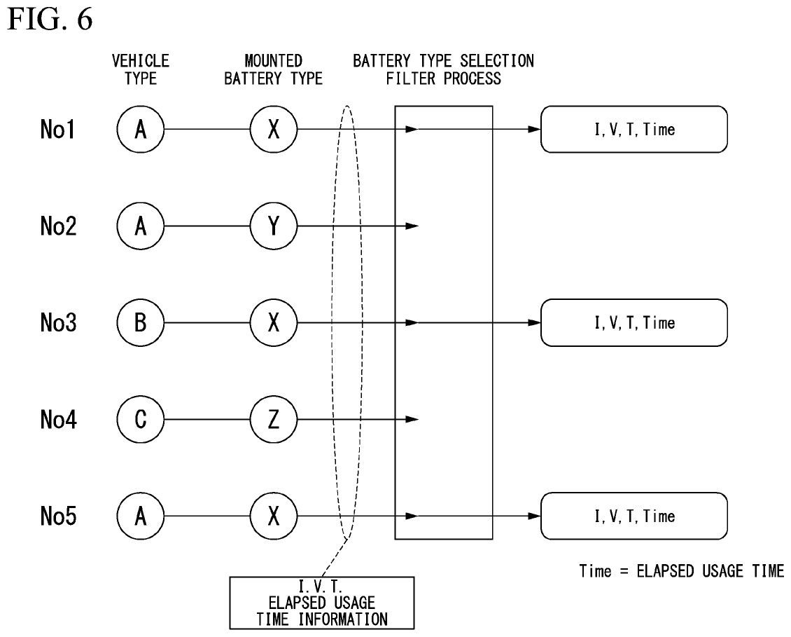

FIG. 6 is a conceptual diagram showing a process of generating the capacity estimation model 154. As shown in FIG. 6, the model generator 120 applies data of the battery use status information (the current value (I), the voltage value (V), and the temperature (T)) of the battery included in the collected data 152 and the total elapsed usage time (Time) to a battery type selection filter. In the example shown in FIG. 6, data is provided from No. 1 to No. 5 vehicles.

The model generator 120 selects the collected data 152 on the basis of battery type information or vehicle type information which is added to the collected data 152. The model generator 120 may select the collected data 152 on the basis of the battery type information or may select the collected data 152 on the basis of the battery type information and the vehicle type information. The model generator 120 selects the battery use status information and the total elapsed usage time of the same type of batteries (or the same type of batteries which are mounted in the same type of vehicles) using the battery type selection filter. In the example shown in FIG. 6, the battery use status information and the total elapsed usage time of batteries of type “X” are selected.

Accordingly, use status information and total elapsed usage times of five batteries of No. 1 to No. 5 are shown in FIG. 6, and the model generator 120 selects three pieces of data of No. 1, No. 3, and No. 5 as information on batteries of type “X.”

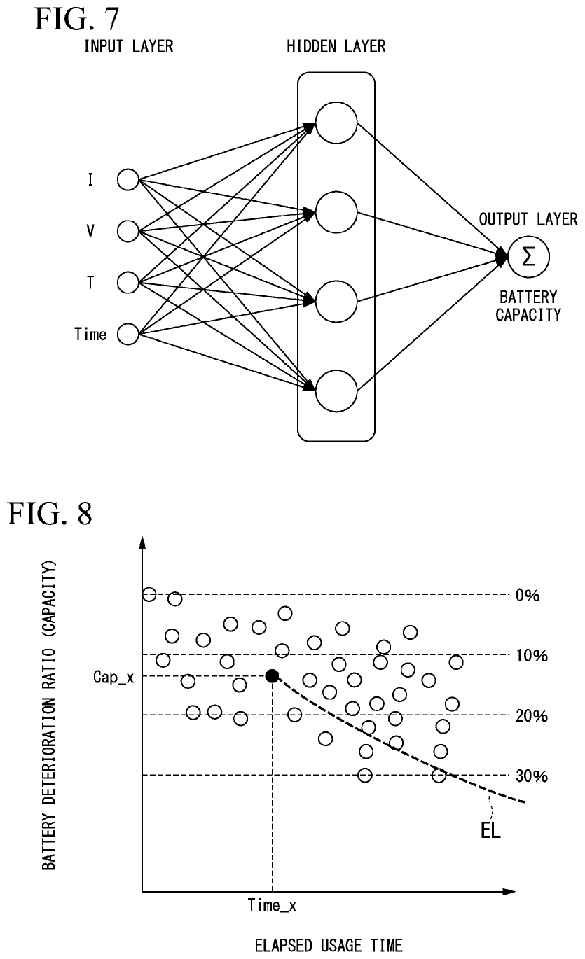

FIG. 7 is a conceptual diagram showing the process of generating the capacity estimation model 154 which is subsequent to FIG. 6. As shown in FIG. 7, the model generator 120 generates the capacity estimation model 154 including an input layer, a hidden layer, and an output layer. The current value (I), the voltage value (V), and the temperature (T) which are items of the battery use status information and the total elapsed usage time (Time) are input to the input layer. A battery capacity is output from the output layer. The hidden layer includes a multi-layered neural network connecting the input layer and the output layer. Parameters of the hidden layer are optimized by performing machine learning using the input of the input layer as learned data and using data to be output from the output layer as training data.

The model generator 120 generates (updates) the capacity estimation model 154 by performing machine learning in which the battery use status information and the total elapsed usage time selected in FIG. 6 are input to the input layer. In this way, the model generator 120 generates the capacity estimation model 154 of the batteries of type “X” for each type of batteries and stores the generated capacity estimation model in the storage 150.

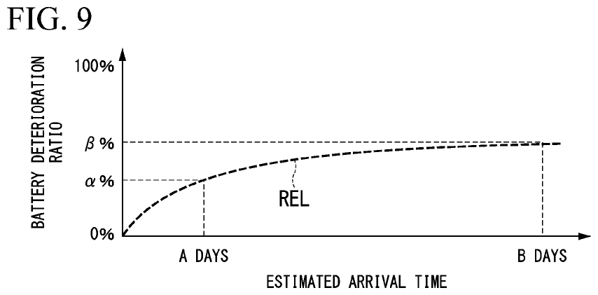

Referring back to the flowchart shown in FIG. 5, the center server 100 causes the model generator 120 to generate the deterioration ratio transition model 156 after generating the capacity estimation model 154 (Step S14). The model generator 120 generates the deterioration ratio transition model 156, for example, as follows. A deterioration ratio transition model generating process will be described below with reference to FIG. 8.

FIG. 8 is a diagram showing the deterioration ratio transition model generating process. The model generator 120 integrates a battery capacity which is an output at the time of generating of the capacity estimation model 154. At the time of integrating of the battery capacity which is an output, the model generator 120 acquires the total elapsed usage time of the battery when the battery capacity is integrated for the battery capacity. White circles shown in FIG. 8 visualize data indicating a relationship between the battery capacity estimated by the capacity estimation model 154 and the total elapsed usage time of the battery at the time of estimation of the battery capacity. The model generator 120 adds the data indicating the relationship between the battery capacity and the total elapsed usage time whenever the capacity estimation model 154 is generated.

The model generator 120 generates a plurality of transition lines by joining data pieces including identification information of the same vehicle 10 from the data indicating the relationship between the integrated battery capacity and the total elapsed usage time. The model generator 120 generates a deterioration ratio transition model 156 by performing statistical processing such as cluster processing on the plurality of generated transition lines. For example, as shown in FIG. 8, a transition line EL which is a deterioration curve indicating transition of the deterioration ratio of the battery is generated as the deterioration ratio transition model 156 for the data of the integrated battery capacity Cap_x and the total elapsed usage time Time_x. The model generator 120 calculates a representative transition by performing regression analysis on the deterioration ratio transition model 156. The deterioration ratio transition model 156 may include only one representative transition line out of the plurality of transition lines or may include a plurality of representative transition lines.

FIG. 9 is a diagram showing a representative transition line REL. As shown in FIG. 9, the model generator 120 generates, for example, a representative transition line REL as a graph with a vertical axis representing a battery deterioration ratio and a horizontal axis representing an estimated arrival time. The model generator 120 stores the generated representative transition line REL in the storage 150. The model generator 120 stores the representative transition line REL for each type of battery in the storage 150.

Referring back to the flowchart shown in FIG. 5, subsequently, the center server 100 causes the deriver 130 to read the designated deterioration ratio information 158 of the battery mounted in the target vehicle 10X from the storage 150 (Step S15). The deriver 130 estimates and derives a designated deterioration ratio arrival time on the basis of the representative transition line REL stored in the storage 150 and the designated deterioration ratio information read from the storage 150 (Step S16). The deriver 130 estimates and derives a lifespan which is a future state of the battery mounted in the target vehicle 10X as the designated deterioration ratio arrival time.

For example, the deriver 130 reads the representative transition line REL included in the deterioration ratio transition model 156 of the battery of type “X,” the current capacity and the total elapsed usage time of the battery mounted in the target vehicle 10X, and the designated deterioration ratio information 158 designated by a user of the target vehicle 10X. The deriver 130 derives the designated deterioration ratio arrival time by applying the current capacity, the total elapsed usage time, and the designated deterioration ratio information of the battery to the read representative transition line REL. The designated deterioration ratio arrival time is expressed by at least one of designated deterioration ratio arrival days (durability days) and designated deterioration ratio arrival years (durability years). For example, as shown in FIG. 9, when the designated deterioration ratio designated by the user of the target vehicle 10X is α%, the estimated arrival time is A days, the designated deterioration ratio arrival days is A days, and the designated deterioration ratio arrival years is A/12 years. When the designated deterioration ratio designated by the user of the target vehicle 10X is β%, the estimated arrival time is B days, the designated deterioration ratio arrival days is B days, and the designated deterioration ratio arrival years is B/12 years. The designated deterioration ratio arrival days and the designated deterioration ratio arrival years are calculated as integers by rounding up, rounding down, or rounding off fractions to the nearest number. They may be calculated as the nearest whole integer

When the deriver 130 derives the designated deterioration ratio arrival time, the center server 100 causes the communicator 110 to transmit designated deterioration ratio arrival time information of the battery mounted in the target vehicle 10X to the target vehicle 10X (Step S17). In this way, the center server 100 ends the process routine shown in FIG. 5.

The target vehicle 10X receives the designated deterioration ratio arrival time information transmitted from the center server 100 via the communication device 50 shown in FIG. 1. The communication device 50 outputs the received designated deterioration ratio arrival time information to the display device 60. The display controller 64 of the display device 60 causes the display 62 to display the designated deterioration ratio arrival days T1 shown in FIG. 4 on the basis of the output designated deterioration ratio arrival time information. The display controller 64 causes the display 62 to display the battery SOC meter M1 output from the controller 36. In the example shown in FIG. 4, 4380 days is displayed as the designated deterioration ratio arrival days T1 and about 90% is displayed as the battery SOC meter M1. The display device 60 may cause the display 62 to display information other than the designated deterioration ratio arrival days T1 and the battery SOC meter M1, for example, a battery deterioration ratio or a designated deterioration ratio. In this case, the center server 100 may transmit the battery deterioration ratio or the designated deterioration ratio to the target vehicle 10X. Instead of or in addition to the designated deterioration ratio arrival days T1, the designated deterioration ratio arrival years may be displayed.

According to the aforementioned first embodiment, the model generator 120 of the center server 100 generates a battery deterioration model and calculates a designated deterioration ratio arrival time as the lifespan of the battery 40 mounted in the target vehicle 10X on the basis of the generated battery deterioration model. The battery deterioration model is generated on the basis of the degrees of deterioration of batteries of vehicles 10 in the market. Accordingly, the center server 100 derives the degree of deterioration of a battery on the basis of data acquired from a plurality of vehicles 10, it is possible to accurately derive the degree of deterioration of a battery mounted in an target vehicle 10X.

The model generator 120 derives a representative transition line on the basis of the battery deterioration model and calculates the lifespan of the battery 40 mounted in the target vehicle 10X on the basis of the representative transition line and the designated deterioration ratio. Accordingly, since a change of battery deterioration over time can be predicted, it is possible to more accurately derive the degree of deterioration of a battery. The model generator 120 generates the battery deterioration model by machine learning. Accordingly, since accuracy of the battery deterioration model can be enhanced with an increase in the number of pieces of data, it is possible to generae an accurate battery deterioration model.

According to the first embodiment, the derived designated deterioration ratio arrival time is displayed on the display 62 provided in the target vehicle 10X as designated deterioration ratio arrival days or designated deterioration ratio arrival years. Accordingly, it is possible to notify the user of the target vehicle 10X of the degree of deterioration of the battery mounted in the target vehicle 10X with high accuracy.

### Second Embodiment

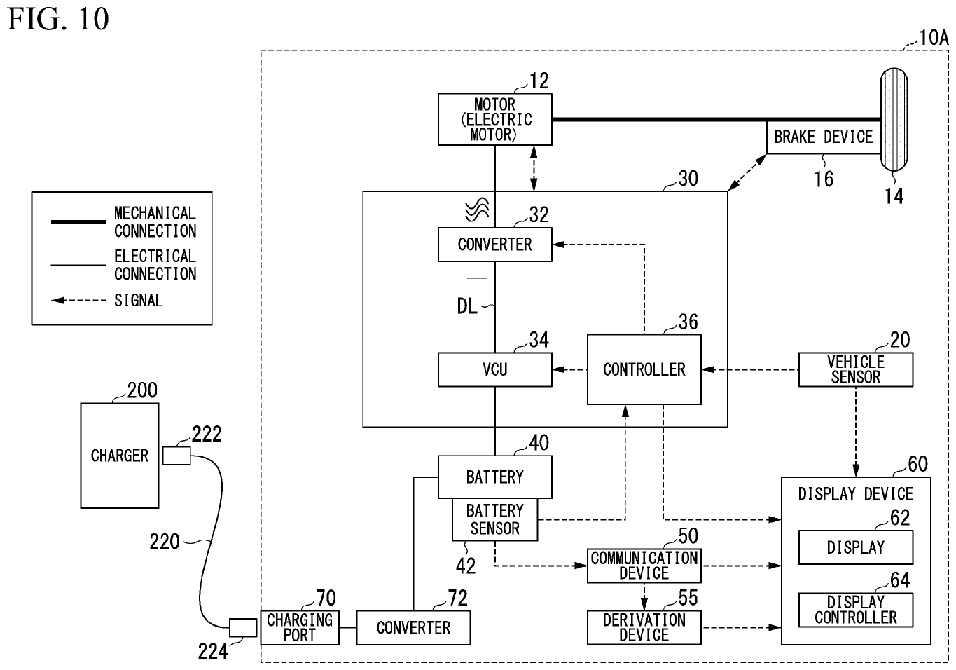

A second embodiment will be described below. FIG. 10 is a diagram showing an example of a configuration of a vehicle 10A according to the second embodiment. The configuration according to the second embodiment is different from the configuration according to the first embodiment, in that an element having the same function as the deriver 130 provided in the center server 100 is provided as a derivation device 55 in the vehicle 10A. The configuration according to the second embodiment is almost the same as the configuration according to the first embodiment in the other points. Processes in the second embodiment will be described below with a focus on differences from the first embodiment.

The derivation device 55 includes a deriver having the same configuration as the deriver 130 of the first embodiment and a storage having the same configuration as the storage 150. The storage of the derivation device 55 stores a designated deterioration ratio in the vehicle 10A. In the second embodiment, the center server 100 transmits a capacity estimation model 154 generaed by the model generator 120 to the vehicle 10A via the communicator 110. The vehicle 10A causes the communication device 50 to receive the transmitted capacity estimation model 154 and to output the received capacity estimation model 154 to the derivation device 55. The derivation device 55 calculates a designated deterioration ratio arrival time on the basis of the capacity estimation model 154 output from the communication device 50 and the designated deterioration ratio stored in the storage. The derivation device 55 outputs the calculated designated deterioration ratio arrival time to the display device 60. The display device 60 causes the display 62 to display the designated deterioration ratio arrival days T1 shown in FIG. 4 on the basis of the output designated deterioration ratio arrival time.

According to the aforementioned second embodiment, similarly to the first embodiment, the model generator 120 of the center server 100 generates a battery deterioration model based on the degrees of deterioration of batteries of vehicles 10A in the market. Accordingly, it is possible to accurately derive the degree of deterioration of a battery mounted in a vehicle 10A.

In the second embodiment, the vehicle 10A stores the designated deterioration ratio which is used to calculate the designated deterioration ratio arrival time of the battery mounted in the vehicle 10A, and the center server 100 does not store the designated deterioration ratio for the vehicle 10A. Since the designated deterioration ratio is not used to calculate a designated deterioration ratio arrival time of a battery mounted in a vehicle 10A other than the individual vehicles 10A, it is possible to decrease the amount of unnecessary information stored in the center server 100. As a result, it is possible to contribute to a decrease in the amount of information stored in the center server 100.

### Third Embodiment

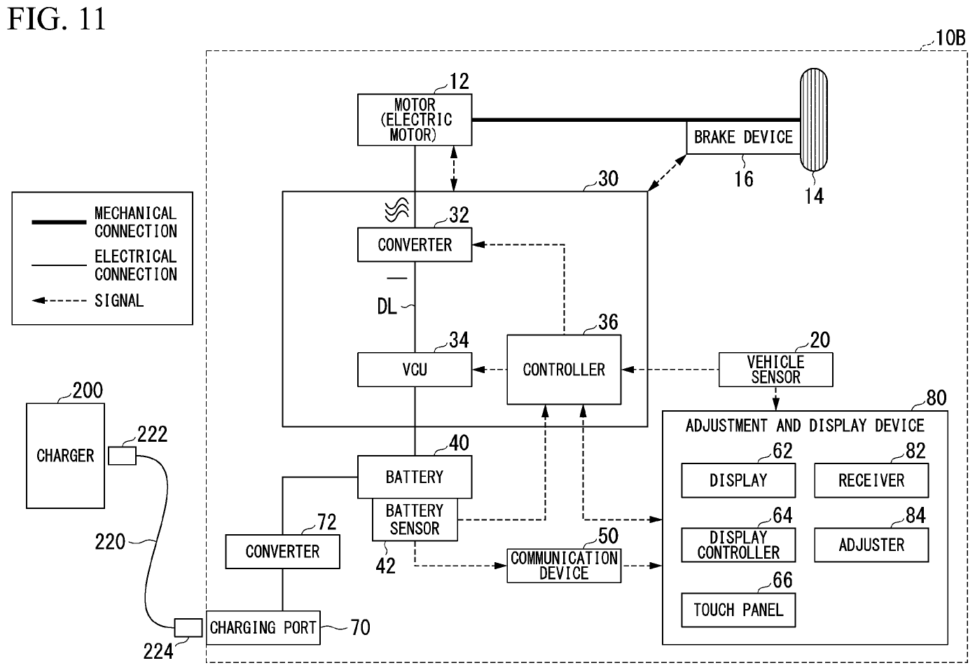

A third embodiment will be described below. FIG. 11 is a diagram showing an example of a configuration of a vehicle 10B according to the third embodiment. The configuration according to the third embodiment is different from the configuration according to the first embodiment, in that an adjustment and display device 80 shown in FIG. 11 is provided instead of the display device 60 shown in FIG. 1. The display device 60 according to the first embodiment displays a lifespan of a battery 40 as a future state, but the adjustment and display device 80 according to the third embodiment also displays a residual value of the battery 40 as a future state. The configuration according to the third embodiment is almost the same as the configuration according to the first embodiment in the other points. The third embodiment will be described below with a focus on differences from the first embodiment.

As shown in FIG. 11, a vehicle 10B includes an adjustment and display device 80. The adjustment and display device 80 includes a display 62, a display controller 64, a touch panel 66, a receiver 82, and an adjuster 84. The display 62 has the same function as in the first embodiment. Similarly to the first embodiment, the display controller 64 causes the display 62 to display designated deterioration ratio arrival days and the like as information associated with the lifespan of the battery 40 and to display an interface screen including a plurality of residual value transition lines indicating transition of a residual value of the battery 40 as objects based on the residual value of the battery 40 on the touch panel 66 on the basis of the information output from the communication device 50.

The touch panel 66 is provided, for example, at a position close to a driver's seat on the instrument panel 93 shown in FIG. 3. The touch panel 66 is disposed, for example, at a position which can be easily operated by a driver who sits on the driver's seat. The touch panel 66 displays a graphical user interface (GUI) switch which can be operated by an occupant. A display mode of a GUI switch will be described later.

The receiver 82 receives an occupant's operation of a GUI switch and generates reception information based on the occupant's operation. The reception information includes a transition of the residual value of the battery 40. The receiver 82 outputs the generated reception information to the adjuster 84. The adjuster 84 generates adjustment information based on the occupant's operation on the basis of the reception information output from the receiver 82. The adjuster 84 outputs the generated adjustment information to the controller 36 and adjusts a use mode associated with the deterioration of the battery 40.

A process routine other than the same process routine as in the first embodiment which is performed by the center server 100 according to the third embodiment will be described below. The center server 100 causes the model generator 120 to classify a plurality of batteries 40 depending on use modes thereof on the basis of battery use status information transmitted from a plurality of vehicles 10B. The center server 100 generates a plurality of transition lines on the basis of the battery capacities of the plurality of classified batteries 40.

The center server 100 may classify the use modes of the batteries 40 in any way. For example, the center server 100 may classify the use modes of the batteries 40 into a use mode in which a priority is put on curbing of deterioration of a battery 40 such that the residual value of the battery 40 increases and a use mode in which a priority is given to performance of a vehicle 10B (hereinafter referred to as “vehicle performance”) such that the residual value of the battery decreases regardless of the deterioration of the battery 40.

For example, when an SOC use range of the battery 40 is narrowed, a maximum traveling distance decreases and the vehicle performance decreases, but the deterioration in SOC does not progress and a durability time of the battery 40 increases. As a result, the residual value of the battery 40 increases. On the other hand, when the SOC use range of the battery 40 is widened, the maximum traveling distance increases and the vehicle performance increases, but the deterioration in SOC progresses thereby and the durability time of the battery 40 decreases. As a result, the residual value of the battery 40 decreases.

With a focus on this point, the model generator 120 classifies the batteries 40 into modes in which the residual value of the battery 40 are different. Specifically, the model generator 120 classifies use of a battery 40 with the narrowed SOC use range into the used mode in which a priority is given to curbing of deterioration of the battery 40 such that the residual value of the battery 40 increases and classifies use of a battery 40 with the widened SOC use range into the use mode in which a priority is given to the vehicle performance such that the residual value of the battery 40 decreases. For example, the model generator 120 may divide and classify the batteries 40 into a plurality of steps, for example, four steps.

In the vehicle 10B, the adjuster 84 adjusts the SOC use range of the battery 40 in the use mode of the battery 40 by outputting adjustment information to the controller 36. For example, the adjuster 84 adjusts the SOC use range of the battery 40 such that the SOC use range of the battery 40 changes to a 32% range of 44% to 76% of the actual SOC, a 35% range of 30% to 65% of the actual SOC, a 50% range of 40% to 90% of the actual SOC, and a 60% range of 30% to 90% of the actual SOC.

The classification of a plurality of batteries 40 may be performed on the basis of a factor other than the SOC use range. For example, when cooling performance of a battery 40 is increased, the deterioration of the battery 40 can be curbed and the residual value of the battery 40 can be increased, but the vehicle performance of the vehicle 10B is decreased thereby. Accordingly, the model generator 120 may classify a plurality of batteries 40 depending on the cooling performance of the batteries 40. When vehicles having a battery 40 mounted therein are, for example, hybrid vehicles, a plurality of batteries 40 may be classified such that the priority of use of an engine (an internal combustion engine) with respect to use of the battery 40 varies.

For example, in a hybrid vehicle, as a ratio of travel with a motor activated to travel with an engine activated becomes lower, it is possible to further curb the deterioration of the battery 40 and to increase the residual value of the battery 40. Accordingly, the model generator 120 may classify a plurality of batteries 40 depending on the ratio of travel with a motor activated to travel with an engine activated.

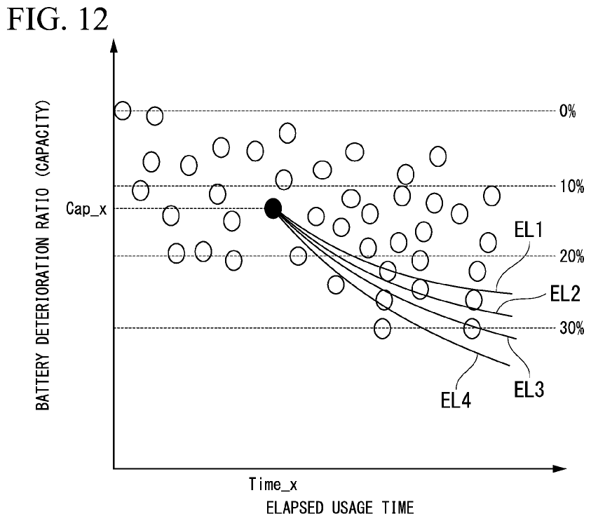

FIG. 12 is a diagram showing an example of a plurality of transition lines. The model generator 120 generates transition lines with a decrease of the residual value of the battery 40. A first transition line EL1 in FIG. 12 is a transition line in which the residual value of the battery 40 is the highest. A second transition line EL2 is a transition line in which the residual value of the battery 40 is the secondly highest, and a third transition line EL3 is a transition line in which the residual value of the battery 40 is the thirdly highest. A fourth transition line EL4 is a transition line in which the residual value is the lowest.

The model generator 120 outputs transition line information corresponding to the plurality of generated transition lines to the communicator 110. The communicator 110 transmits the transition line information output from the model generator 120 to the vehicle 10B. In this way, the center server 100 transmits the transition line information to the vehicle 10B.

A process routine when the transition line information transmitted from the center server 100 is received by the vehicle 10B will be described below. The vehicle 10B receives the transition line information transmitted form the center server 100 via the communication device 50. The communication device 50 outputs the received transition line information to the adjustment and display device 80. The display controller 64 generates residual value transition lines on the basis of the transition line information output from the communication device 50 and the adjustment and display device 80 displays the generated residual value transition lines on the touch panel 66.

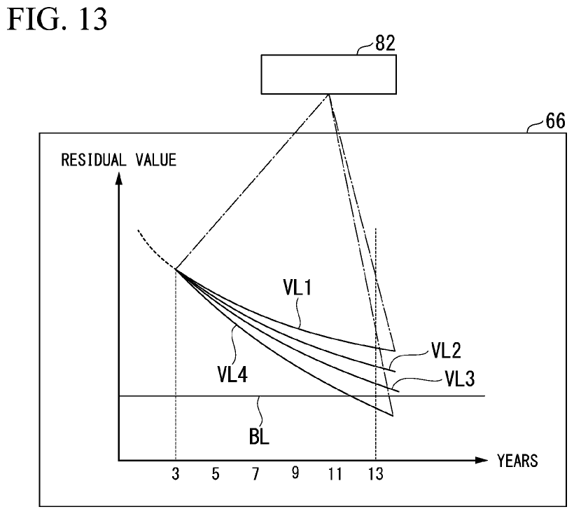

The residual value of a battery 40 changes depending on a deterioration ratio of the battery 40, and the residual value of the battery 40 decreases when the deterioration ratio of the battery 40 increases. FIG. 13 is a diagram showing an example of a plurality of residual value transition lines displayed on the touch panel 66. The display controller 64 generates a first residual value transition line VL1 shown in FIG. 13 on the basis of the first transition line EL1 shown in FIG. 12. Similarly, the display controller 64 generates second to fourth residual value transition lines VL2 to VL4 shown in FIG. 13 on the basis of the second to fourth transition lines EL2 to EL4 shown in FIG. 12. The first to fourth residual value transition lines VL1 to VL4 are objects indicating the transition of the residual values derived by the deriver. The display controller 64 displays an interface screen including the generated first to fourth residual value transition lines VL1 to VL4 on the touch panel 66.

The display controller 64 displays an interface screen including a lower limit line BL along with the first to fourth residual value transition lines VL1 to VL4 on the touch panel 66. The lower limit line is a line indicating a lower limit of the residual value at which the battery 40 can be used as an onboard battery. The lower limit line BL is a line indicating a deterioration allowable limit of the battery 40. After the first to fourth residual value transition lines VL1 to VL4 have become lower than the lower limit line BL, it is estimated that the battery 40 does not satisfy performance of an onboard battery. The lower limit line BL may be used, for example, as a line with which use of the battery 40 is guaranteed by a seller of the vehicle 10B.

The first to fourth residual value transition lines VL1 to VL4 displayed on the touch panel 66 serve as GUI switches and constitute a part of the receiver 82. In other words, a display mode of the GUI switches is a mode in which the first to fourth residual value transition lines VL1 to VL4 are displayed. The receiver 82 receives an operation of one of the first to fourth residual value transition lines VL1 to VL4 in a state in which the display controller 64 displays the interface screen on the touch panel 66.

For example, when an occupant who is a user operates the first residual value transition line VL1, the receiver 82 receives the operation of the first residual value transition line VL1. The operation of the first residual value transition line VL1 is, for example, an operation with which the occupant touches the first residual value transition line VL1. The occupant can select the residual value of the battery 40 corresponding to the occupant's taste by selecting and operating one of the first to fourth residual value transition lines VL1 to VL4.

When the operation of the first residual value transition line VL1 is received, the receiver 82 outputs first reception information to the adjuster 84. Similarly, when operations of the second to fourth residual value transition lines VL2 to VL4 are received, the receiver 82 outputs second to fourth reception information to the adjuster 84.

The first reception information is information for setting the residual value of the battery 40 to the highest value. The second reception information is information for setting the residual value of the battery 40 to the secondly highest value and the third reception information is information for setting the residual value of the battery 40 to the thirdly highest value. The fourth reception information is information for setting the residual value of the battery 40 to the lowest value. The adjuster 84 adjusts the use mode associated with the deterioration of the battery 40 on the basis of the transition of the residual value of the battery 40 included in the first to fourth reception information received by the receiver 82.

For example, the adjuster 84 adjusts the SOC use range of the battery 40 in the use mode associated with the deterioration of the battery 40. Specifically, when the first reception information is output from the receiver 82, the adjuster 84 outputs first adjustment information to the controller 36, and sets the SOC use range of the battery 40 to the narrowest range. In this case, the deterioration of the battery 40 is curbed and the durability time of the battery 40 is increased, but the vehicle performance is decreased. When the second reception information is output from the receiver 82, the adjuster 84 outputs second adjustment information to the controller 36, and sets the SOC use range of the battery 40 to a narrow range. In this case, the deterioration of the battery 40 is more likely to progress in comparison with a case in which the first adjustment information is output, but the vehicle performance is increased.

When the third reception information is output from the receiver 82, the adjuster 84 outputs third adjustment information to the controller 36 and sets the SOC use range of the battery 40 to a wide range. In this case, the deterioration of the battery 40 is less likely to progress in comparison with a case in which the second adjustment information is output, but the vehicle performance is increased. When the fourth reception information is output from the receiver 82, the adjuster 84 outputs fourth adjustment information to the controller 36 and sets the SOC use range of the battery 40 to the widest range. In this case, the deterioration of the battery 40 is more likely to progress in comparison with a case in which the third adjustment information is output, but the vehicle performance is increased.

The adjuster 84 adjusts the SOC use range of the battery 40 in the use mode associated with the deterioration of the battery 40, but may adjust a priority of exhibition of vehicle performance with respect to curbing of deterioration of the battery 40. For example, when reception information for increasing the residual value of the battery 40 is output from the receiver 82, the adjuster 84 adjusts the priority level of exhibition of vehicle performance with respect to curbing of deterioration of the battery 40 to be lower.

When the vehicle 10B is a hybrid vehicle, the adjuster 84 may adjust a priority level of use of an engine provided in the hybrid vehicle with respect to use of the battery 40 as a use mode associated with the deterioration of the battery 40. When reception information for increasing the residual value of the battery 40 is output from the receiver 82, the adjuster 84 adjusts the priority level of use of the engine provided in the hybrid vehicle with respect to use of the battery 40 to be lower.

According to the aforementioned third embodiment, similarly to the first embodiment, the model generator 120 of the center server 100 generates a battery deterioration model based on the degrees of deterioration of batteries of vehicles 10B in the market. Accordingly, it is possible to accurately derive the degree of deterioration of a battery mounted in a vehicle 10B.

In the third embodiment, the residual value transition lines indicating transitions of the residual value of the battery 40 is displayed on the touch panel 66. Accordingly, a user can easily understand a future residual value of the battery 40. Since a plurality of residual value transition lines are displayed on the touch panel 66, a user can easily understand variation of the residual value of the battery 40 depending on the vehicle 10B and the use mode of the battery 40.

By allowing an occupant to operate one of a plurality of residual value transition lines, it is possible to adjust priority levels of curbing of deterioration of the battery 40 and vehicle performance Accordingly, the use state and the future state of the battery 40 can be made to satisfy a user's taste that the user wants to enjoy comfortable driving even with riding a vehicle 10B down and a user's taste that the user wants to increase the residual value of the battery 40 or to increase the durability time of the battery 40 even with decreasing vehicle performance Since the lower limit line BL is displayed on the touch panel 66, a user can arbitrarily adjust a timing at which a residual value transition line is below the lower limit line by selecting the residual value transition line.

The SOC use range of the battery 40 may be adjusted on the basis of the relationship between the residual value transition line and the lower limit line BL. For example, when the residual value transition line is estimated to be below the lower limit line BL at a predetermined timing, the residual value transition line may be made not to be below the lower limit line at a predetermined timing by prohibiting widening of the SOC use range of the battery 40.

In the third embodiment, the residual value transition lines associated with the residual value of the battery 40 are displayed on the touch panel 66, but a screen associated with the residual value of the battery 40 may be displayed on a display other than the touch panel 66, for example, the display 62 or the second display device 95. In this case, the degree of curbing of the deterioration of the battery 40 may be received using a switch other than a GUI switch. In the third embodiment, both the lifespan and the residual value of the battery are displayed as the future state of the battery 40, but a screen associated with the residual value may be displayed without displaying information on the lifespan of the battery.

In the third embodiment, the display controller 64 displays a plurality of residual value transition lines and the receiver 82 receives the transition of the residual value of the battery selected by an occupant out of the plurality of residual value transition lines, but the transition of the residual value of the battery may be received in another manner. For example, the display controller 64 displays the residual value transition lines and moves (deforms) a residual value transition line by allowing an occupant to swipe or pinch a part of the residual value transition line, or the like. The receiver 82 may receive the transition of the residual value of the battery on the basis of the moved (deformed) residual value transition line. In this case, the display controller 64 may set the number of residual value transition lines displayed on the touch panel 66 to one.

### Modified Examples

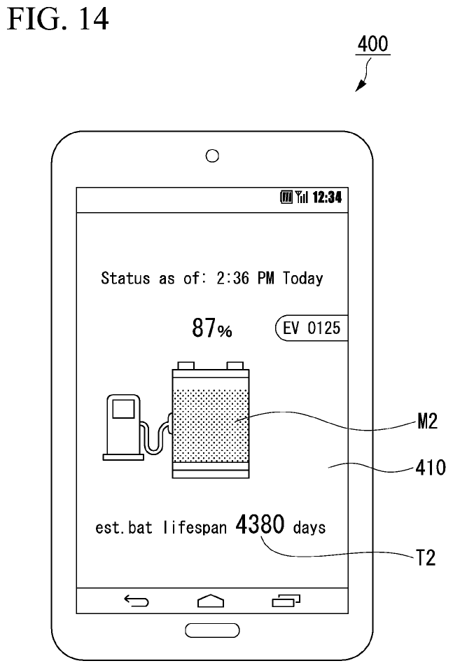

In the aforementioned embodiments, the display device 60 displays the designated deterioration ratio arrival time received by the communication device 50 on the display 62 of the target vehicle 10X, but may display the designated deterioration ratio arrival time on another object. For example, instead of or in addition to the operation in which the display controller 64 of the display device 60 of the target vehicle 10X causes the display 62 to display the designated deterioration ratio arrival time, a display controller of the second display device 95 shown in FIG. 3 may cause the display of the second display device 95 to display the designated deterioration ratio arrival time. Alternatively, as shown in FIG. 14, the designated deterioration ratio arrival time may be displayed on an information terminal 400 which is carried by a user of the target vehicle or the like.

The information terminal 400 includes a display 410 and a communicator and a display controller which are not shown. The communicator receives designated deterioration ratio arrival time information transmitted from the center server 100 and outputs the received designated deterioration ratio arrival time information to the display controller. The display controller causes the display 410 to display designated deterioration ratio arrival days T2 shown in FIG. 14 on the basis of the output designated deterioration ratio arrival time information. Battery SOC information associated with the battery SOC of the battery mounted in a vehicle 10 may be transmitted from the communication device 50 of the vehicle 10 to the information terminal 400 and the information terminal 400 may cause the display 410 to display a battery SOC image M2 indicating the battery SOC. In the example shown in FIG. 14, the information terminal is a mobile terminal, but the information terminal may be a terminal which is provided indoor or the like.

In this modified example, even when a user of a vehicle 10 is placed outside of the vehicle 10 or does not turn on a power supply of the display device 60, the user can accurately understand a lifespan of the battery. A person who carries the information terminal 400 may be a person other than the user of the vehicle, for example, a second-hand car dealer. When the owner of the information terminal 400 is a second-hand car dealer, the owner can understand the lifespan of a battery mounted in a vehicle 10 and thus it is possible to enhance the accuracy of evaluation of the value of the vehicle 10.

In the aforementioned embodiments, the designated deterioration ratio is stored in the center server 100 or the vehicle 10 in advance, but another mode may be employed. For example, an input means that inputs a designated deterioration ratio may be provided and a user or the like may input a designated deterioration ratio to the input means, for example, when the user or the like wants to understand the lifespan of the battery.

Some of the processes which are performed by the center server 100 may be performed by the vehicle 10 or some of the processes which are performed by the vehicle 10 may be performed by the center server 100. In this case, information which is transmitted and received between the vehicle 10 and the center server 100 may be appropriately determined depending on information which has been generated.

While the present invention has been described above with reference to an embodiment, the invention is not limited to the embodiment and can be subjected to various modifications and substitutions without departing from the gist of the invention.

### REFERENCE SIGNS LIST

1 . . . Diagnostic system
10, 10A . . . Vehicle
10X . . . Target vehicle
12 . . . Motor
50 . . . Communication device
55 . . . Derivation device
60 . . . Display device
62 . . . Display
64 . . . Display controller
66 . . . Touch panel
70 . . . Charging port
80 . . . Adjustment and display device
82 . . . Receiver
84 . . . Adjuster
93 . . . Instrument panel
94 . . . Driver seat
95 . . . Second display device
100 . . . Center server (diagnostic device)
110 . . . Communicator (acquirer)
120 . . . Model generator
130 . . . Deriver
200 . . . Charger
EL, EL1 to EL4 . . . Transition lines (first to fourth transition lines)
REL . . . Representative transition line
M1 . . . Battery SOC meter
NW . . . Network
T1 . . . Designated deterioration ratio arrival days
VL1 to VL4 . . . First to fourth residual value transition lines

What is claim is:

1.-19. (canceled)

20. A diagnostic device comprising:
an acquirer configured to acquire information indicating a use status and a degree of deterioration of each secondary battery from a plurality of secondary batteries which are mounted in a plurality of vehicles including an target vehicle;
a model generator configured to generate a model that is configured to output a battery capacity in a case where a use state is input thereto on the basis of the information acquired by the acquirer; and
a deriver configured to derive a future state of the secondary battery mounted in the target vehicle using the model;
wherein the future state is a residual value, and
wherein the diagnostic device further comprises a display controller configured to display an interface screen including an object indicating a transition of the residual value derived by the deriver on a display.

21. The diagnostic device according to claim 20, wherein the deriver is further configured to derive deterioration curves of the plurality of secondary batteries on the basis of the model, and to deriver the future state of the secondary battery mounted in the target vehicle on the basis of the deterioration curves and a designated deterioration ratio.

22. The diagnostic device according to claim 20, wherein the model generator is configured to generate the model by machine learning.

23. The diagnostic device according to claim 20, wherein the use status of each secondary battery includes at least one of a current value, a voltage value, a temperature, or a total elapsed usage time of the secondary battery.

24. The diagnostic device according to claim 20, wherein the model generator is configured to generate the model on the basis of information on the same type of secondary batteries.

25. The diagnostic device according to claim 20, wherein the model generator is configured to generate the model on the basis of information on the same type of secondary batteries which are mounted in the same type of vehicles.

26. The diagnostic device according to claim 20, wherein the future state is a lifespan, and
wherein the diagnostic device further comprises a display controller configured to display a lifespan of the secondary battery derived by the deriver on a display.

27. The diagnostic device according to claim 26, wherein the display is provided in the target vehicle.

28. The diagnostic device according to claim 26, wherein the display is provided in a prescribed information terminal.

29. The diagnostic device according to claim 26, wherein the display controller is configured to display the lifespan on the display using at least one of durability years or durability days.

30. The diagnostic device according to claim 20, wherein the diagnostic device further comprises:
a receiver configured to receive the transition of the residual value in a state in which the interface screen is displayed on the display.

31. The diagnostic device according to claim 30, wherein the display controller is configured to display an interface screen including a plurality of objects on the display, and
wherein the receiver is configured to receive transition of the residual value associated with the object selected by a user out of the plurality of objects included in the interface screen.

32. The diagnostic device according to claim 30, wherein the display controller is further configured to display the interface screen including a deterioration allowable limit of the secondary battery on the display.

33. The diagnostic device according to claim 30, further comprising an adjuster configured to adjust a use mode associated with deterioration of the secondary battery on the basis of the transition of the residual value received by the receiver.

34. The diagnostic device according to claim 33, wherein the adjuster is configured to adjust an SOC use range of the secondary battery as the use mode associated with deterioration of the secondary battery.

35. The diagnostic device according to claim 33, wherein the adjuster is configured to adjust a priority of performance exhibition of the vehicle with respect to curbing of deterioration of the secondary battery as the use mode associated with deterioration of the secondary battery.

36. The diagnostic device according to claim 33, wherein the vehicle is a hybrid vehicle including the secondary battery and an internal combustion engine, and
wherein the adjuster is configured to adjust a priority of use of the internal combustion engine with respect to curbing of deterioration of the secondary battery as the use mode associated with deterioration of the secondary battery.

37. A diagnostic method using a computer, comprising:
acquiring information indicating a use status and a degree of deterioration of each secondary battery from a plurality of secondary batteries which are mounted in a plurality of vehicles including an target vehicle;
generating a model that is configured to output a battery capacity in a case where a use state is input thereto on the basis of the acquired information; and
deriving a future state of the secondary battery mounted in the target vehicle using the model;
wherein the future state is a residual value, and
wherein the diagnostic method comprises executing a process to display an interface screen including an object indicating a transition of the derived residual value on a display.

38. A program for causing a computer to:
acquire information indicating a use status and a degree of deterioration of each secondary battery from a plurality of secondary batteries which are mounted in a plurality of vehicles including an target vehicle;
generate a model that is configured to output a battery capacity in a case where a use state is input thereto on the basis of the acquired information; and
derive a future state of the secondary battery mounted in the target vehicle using the model;
wherein the future state is a residual value, and
wherein the program causes the computer to display an interface screen including an object indicating a transition of the derived residual value on a display.
